(19) United States
(12) Patent Application Publication
(10) Pub. No.: US 2024/0142545 A1
(43) Pub. Date: May 2, 2024

(54) POWER SUPPLY ABNORMALITY DETECTION CIRCUIT

(71) Applicant: LAPIS Technology Co., Ltd., Yokohama (JP)

(72) Inventor: Takahiro YONEDA, Yokohama (JP)

(73) Assignee: LAPIS Technology Co., Ltd., Yokohama (JP)

(21) Appl. No.: 18/489,848

(22) Filed: Oct. 19, 2023

(30) Foreign Application Priority Data
Oct. 31, 2022 (JP) 2022-174897

(51) Int. Cl. G01R 31/40; G01R 23/00

(52) U.S. Cl. CPC G01R 31/40; G01R 23/005

(57) ABSTRACT

Provided is a power supply abnormality detection circuit capable of detecting a power supply abnormality using a logic circuit.

The power supply abnormality detection circuit includes a preset first dividing circuit part dividing a frequency of an input clock signal by a frequency of a first ratio and output the divided frequency, a second dividing circuit part dividing a frequency of the input clock signal by the frequency of the first ratio when a power supply voltage is a normal voltage, and dividing a frequency of an input signal by a frequency of a second ratio different from the first ratio and outputting the divided frequency when the power supply voltage is an abnormal voltage, and a comparison circuit part performing comparison of two signals of an output signal of the first dividing circuit part and an output signal of the second dividing circuit part.

### CROSS-REFERENCE TO RELATED APPLICATION

This application claims the priority benefit of Japan application serial no. 2022-174897, filed on Oct. 31, 2022. The entirety of the above-mentioned patent application is hereby incorporated by reference herein and made a part of this specification.

### BACKGROUND

### Technical Field

The disclosure relates to a power supply abnormality detection circuit.

### Description of Related Art

Patent Document 1 discloses a power supply abnormality detection circuit configured to detect an abnormal state of an output voltage of a power supply by averaging control signals, pulse widths of which are modulated, according to a direct current output voltage and comparing outputs thereof with a reference value.

### PATENT DOCUMENTS

Japanese Patent Application Laid-Open (JP-A) No. H06-083541

In the power supply abnormality detection circuit of JP-A No. H06-083541, in order to detect a power supply abnormality, an analog circuit constituted by a reference voltage circuit, a register, a comparator, and the like is installed. However, in such an analog circuit, a circuit area may increase, and further, the circuit may be susceptible to noise

### SUMMARY

A power supply abnormality detection circuit of a first embodiment includes a first dividing circuit part configured to divide a frequency of an input clock signal by a frequency of a preset first ratio and output the divided frequency; a second dividing circuit part configured to divide a frequency of the input clock signal by the frequency of the first ratio when a power supply voltage is a normal voltage, and divide a frequency of an input signal by a frequency of a second ratio different from the first ratio and output the divided frequency when the power supply voltage is an abnormal voltage; and a comparison circuit part configured to perform comparison of two signals of an output signal of the first dividing circuit part and an output signal of the second dividing circuit part.

### BRIEF DESCRIPTION OF THE DRAWINGS

FIG. 1 is a view showing a circuit configuration of a power supply abnormality detection circuit of a first embodiment of the disclosure.

FIG. 2 is a view showing a detailed circuit configuration of a second dividing circuit part in the power supply abnormality detection circuit.

FIG. 3 is a truth table of a flip-flop circuit.

FIG. 4 is a timing chart showing a state of a signal in each part of the power supply abnormality detection circuit.

FIG. 5 is a view showing a circuit configuration of a power supply abnormality detection circuit of a second embodiment of the disclosure.

FIG. 6 is a timing chart showing a state of a signal in each part of the power supply abnormality detection circuit.

FIG. 7 is a view showing a circuit configuration of a power supply abnormality detection circuit of a third embodiment of the disclosure.

### DESCRIPTION OF THE EMBODIMENTS

In consideration of the above-mentioned circumstances, the disclosure is directed to providing a power supply abnormality detection circuit capable of detecting a power supply abnormality using a logic circuit.

In the power supply abnormality detection circuit of the first embodiment, according to the power supply abnormality detection circuit of a second embodiment, the second dividing circuit part includes a delay circuit configured to change a delay time according to an operating voltage, and a first flip-flop circuit configured to input the output signal via the delay circuit.

In the power supply abnormality detection circuit of the second embodiment, according to a power supply abnormality detection circuit of a third embodiment, the delay circuit generates a delay of one cycle or more and less than two cycles of the frequency of the clock signal input to the first flip-flop circuit at the normal voltage, and generates a delay of less than one cycle of the frequency of the clock signal input to the first flip-flop circuit when a voltage is an abnormal voltage that is higher than the normal voltage.

In the power supply abnormality detection circuit of the second embodiment, according to a power supply abnormality detection circuit of a fourth embodiment, the delay circuit generates a delay of less than one cycle of the frequency of the clock signal input to the first flip-flop circuit at the normal voltage, and generates a delay of one cycle or more and less than two cycles of the frequency of the clock signal input to the first flip-flop circuit when a voltage is an abnormal voltage that is lower than the normal voltage.

In the power supply abnormality detection circuit according to any one of the first embodiment to the fourth embodiment, according to a power supply abnormality detection circuit of a fifth embodiment, the comparison circuit part includes a logic circuit configured to perform an exclusive-or operation of an output signal of the first dividing circuit part and an output signal of the second dividing circuit part; and a second flip-flop circuit configured to synchronize the signal output from the logic circuit with the clock signal input to the first dividing circuit part.

In the power supply abnormality detection circuit of the fifth embodiment, a power supply abnormality detection circuit of a sixth embodiment includes an abnormality determination part configured to determine that the power supply voltage becomes the abnormal voltage when a signal showing that the two signals are in different states is output from the comparison circuit part.

According to the power supply abnormality detection circuit of the disclosure, it is possible to suppress the circuit area and the influence of noise.

### First Embodiment

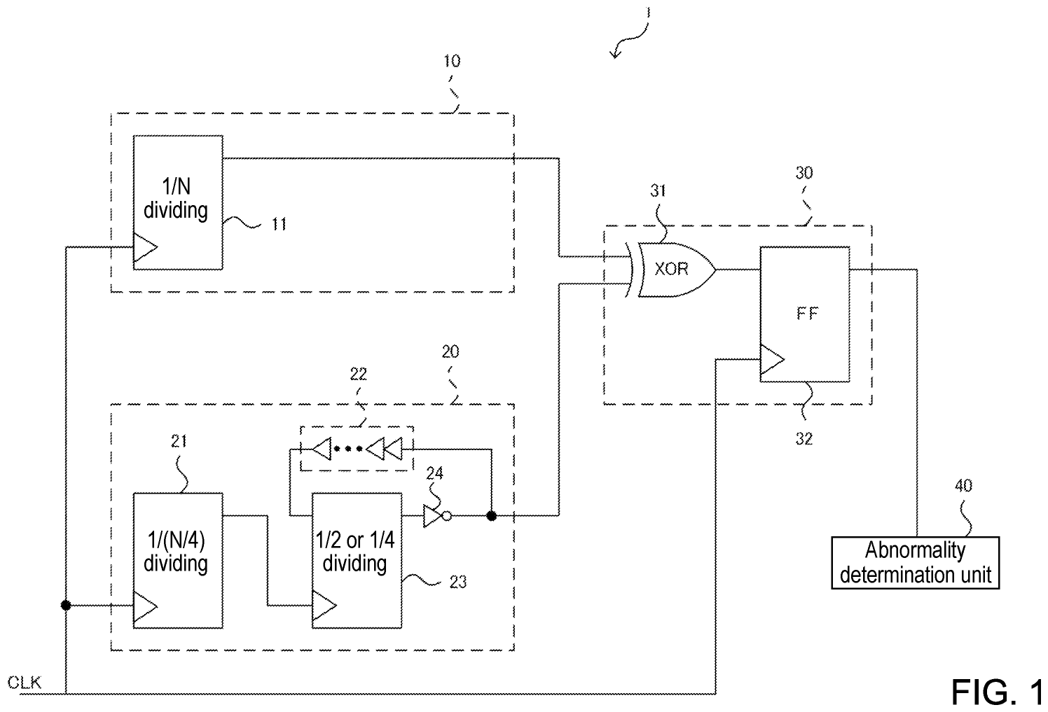

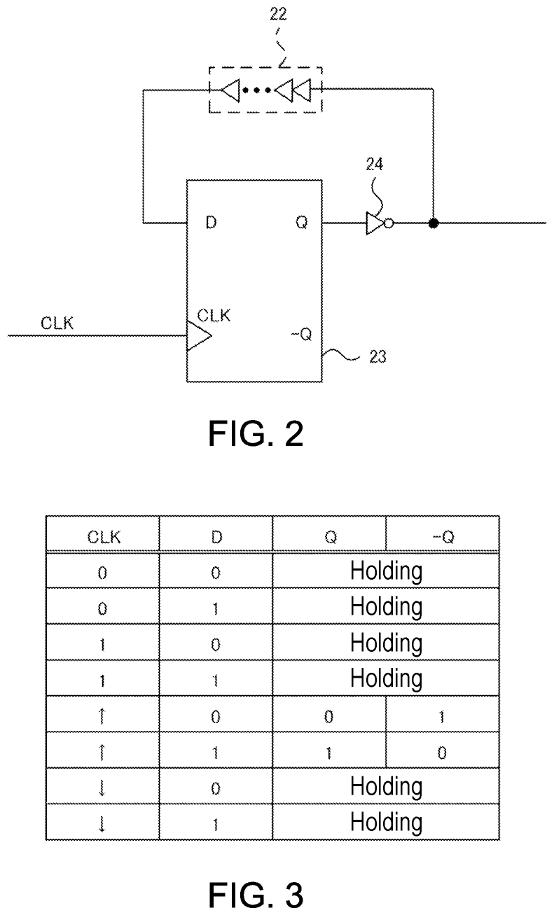

A power supply abnormality detection circuit 1 of a first embodiment of the disclosure will be described with reference to the accompanying drawings. FIG. 1 is a view showing a circuit configuration of the power supply abnormality detection circuit 1 of the first embodiment of the disclosure. FIG. 2 is a view showing a detailed circuit configuration of a second dividing circuit part.

The power supply abnormality detection circuit 1 of the embodiment is a circuit configured to detect a voltage as a power supply abnormality when the voltage increases above a normal voltage, and the power supply abnormality detection circuit 1 is constituted by an integrated circuit such as an integrated circuit (IC), a large scale integration (LSI), or the like.

The power supply abnormality detection circuit 1 includes, as shown in FIG. 1, a first dividing circuit part 10, a second dividing circuit part 20, a comparison circuit part 30, and an abnormality determination part 40.

The first dividing circuit part 10 divides a frequency of a clock signal that was input by a frequency of a preset first ratio and outputs it. Here, the preset first ratio is expressed as 1/N. Further, N is an integer. In the embodiment, for example, N=4, and the first ratio is 1/4.

The first dividing circuit part 10 includes, specifically, a dividing circuit 11 including a flip-flop circuit that functions as a 1/2 dividing circuit. The dividing circuit 11 is a circuit in which flip-flop circuits functioning as 1/2 dividing circuits are connected in multiple stages according to the preset first ratio. Since the first ratio is set as 1/4 in the embodiment, flip-flop circuits that function as 1/2 dividing circuits are connected in two stages. The flip-flop circuit that constitutes the dividing circuit 11 can use, for example, an edge trigger type delay (D) flip-flop circuit.

The second dividing circuit part 20 divides a frequency of the input clock signal by a frequency of a first ratio when a power supply voltage is a normal voltage, and divides a frequency of the input signal by a frequency of a second ratio different from the first ratio and outputs the divided frequency when the power supply voltage is an abnormal voltage.

The second dividing circuit part 20 includes, specifically, a dividing circuit 21 configured to divide a frequency of the input clock signal by a frequency of a ratio of 1/(N/4) and outputs the divided frequency, a delay circuit 22 in which a delay time varies according to an operating voltage, a flip-flop circuit 23 configured to input an output signal via the delay circuit 22, and a NOT circuit 24 configured to invert the output signal of the flip-flop circuit 23.

The dividing circuit 21 is a circuit in which flip-flop circuits functioning as a 1/2 dividing circuit are connected in multiple stages to form a 1/(N/4) dividing circuit. As the flip-flop circuit that constitutes the dividing circuit 21, for example, an edge trigger type D flip-flop circuit can be used.

In the embodiment, since N=4 and the first ratio is 1/4, a dividing ratio in the dividing circuit 21 becomes 1/(4/4)=1, and dividing of the frequency of the input clock signal is not performed. For this reason, the dividing circuit 21 is omitted.

Further, if N=8 and the first ratio is 1/8, a dividing ratio in the dividing circuit 21 becomes 1/(8/4)=1/2, and a 1/2 dividing circuit is connected as the dividing circuit 21.

The delay circuit 22 generates a delay of 1 cycle or more and less than 2 cycles of the frequency of the input clock signal in the flip-flop circuit 23 at the normal voltage, and generates a delay of less than 1 cycle of the frequency of the input clock signal in the flip-flop circuit 23 at the abnormal voltage at which the voltage increases above the normal voltage.

The delay circuit 22 may have any configuration as long as it is a circuit whose delay time changes depending on the operating voltage, and for example, it may be configured by a relay circuit including an inverter such as a metal oxide semiconductor field effect transistor (MOS-FET) relay circuit or the like.

The flip-flop circuit 23 is, for example, an edge trigger type D flip-flop circuit, and specifically, as shown in FIG. 2, includes four input/output terminals such as a signal input terminal D, a clock signal input terminal CLK, an output terminal Q, and an inverting output terminal −Q.

The clock signal output from the dividing circuit 21 is input to the terminal CLK. Further, in the embodiment, since N=4 and the first ratio is 1/4, the dividing circuit 21 is omitted as described above. For this reason, the clock signal is directly input to the terminal CLK without going through the dividing circuit 21.

The signal output from the output terminal Q is input to the terminal D via the NOT circuit 24 and the delay circuit 22.

FIG. 3 is a truth table of the flip-flop circuit 23. As shown in FIG. 3, the flip-flop circuit 23 takes in the value of the signal input to the terminal D at a rising edge of the clock signal, and holds the output in other states.

In the flip-flop circuit 23 configured as described above, the delay time in the delay circuit 22 is longer than one cycle of the frequency of the clock signal input to the flip-flop circuit 23 at the normal voltage, and a setup error occurs in the flip-flop circuit 23.

As a result, in the flip-flop circuit 23, the frequency of the clock signal input to the flip-flop circuit 23 becomes 1/4 because the output is inverted every rising edge of the clock signal with a ratio of once every two pulses of the clock signal.

In addition, when the voltage is an abnormal voltage, which is higher than the normal voltage, the delay time in the delay circuit 22 becomes less than one cycle of the frequency of the clock signal input to the flip-flop circuit 23, and the setup error is eliminated.

As a result, in the flip-flop circuit 23, since the output is inverted every rising edge of the clock signal, the frequency of the clock signal input to the flip-flop circuit 23 becomes 1/2.

Accordingly, the flip-flop circuit 23 is a variable dividing circuit that functions as a 1/4 dividing circuit when the voltage is normal, and functions as a 1/2 dividing circuit when the voltage is abnormal and higher than the normal voltage.

The signal output from the output terminal Q and inverted by the NOT circuit 24 is output to the comparison circuit part 30 as the output signal of the second dividing circuit part 20.

The comparison circuit part 30 performs comparison of two signals, i.e., the output signal of the first dividing circuit part 10 and the output signal of the second dividing circuit part 20.

The comparison circuit part 30 includes, specifically, an XOR circuit 31 configured to perform an exclusive-or operation of the two input signals, and a flip-flop circuit 32 configured to synchronize the signal output from the XOR circuit 31 with the clock signal.

The abnormality determination part 40 determines that the power supply voltage becomes the abnormal voltage when a signal showing that the two signals from the comparison circuit part 30 are different is output. The abnormality determination part 40 is constituted by, for example, a processor configured to execute predetermined processing on the basis of the program stored in the memory.

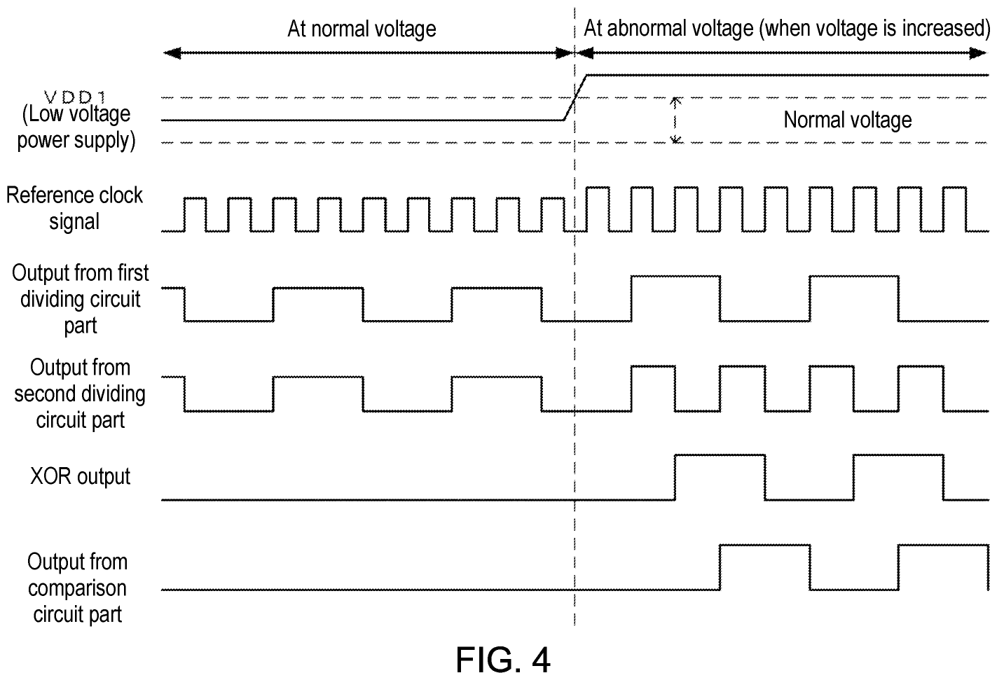

Next, an action of the power supply abnormality detection circuit 1 of the embodiment will be described. FIG. 4 is a timing chart showing a state of the signal in each part of the power supply abnormality detection circuit 1 of the embodiment.

Here, a voltage VDD1 supplied from a low voltage power supply is supplied as an operating voltage of the power supply abnormality detection circuit 1. The voltage VDD1 is, for example, a reference voltage of 1.2 V, and a range of ±0.2 V with the reference voltage of 1.2 V sandwiched therebetween, i.e., a range from 1.0 V to 1.4 V is set as a normal voltage.

The power supply abnormality detection circuit 1 of the embodiment detects the voltage as the abnormal voltage when the voltage is higher than the normal voltage, i.e., when the voltage VDD1 exceeds 1.4 V.

In the following description, a clock signal before being input to the first dividing circuit part 10 and the second dividing circuit part 20 is referred to as a reference clock signal.

As shown in FIG. 4, at the normal voltage, the two signals of the output signal of the first dividing circuit part 10 and the output signal of the second dividing circuit part 20 are in the same phase and have a frequency that is 1/4 of the reference clock signal.

Accordingly, in the signal as the result of performing the exclusive-or operation with respect to these two signals using the XOR circuit 31, the low signal is continuously output. In addition, as for the signal output from the comparison circuit part 30 by synchronizing the signal output from the XOR circuit 31 with the reference clock signal, a low signal is continuously output.

On the other hand, at the abnormal voltage when the voltage is higher than the normal voltage, the output signal of the first dividing circuit part 10 has a frequency of 1/4 with respect to the reference clock signal, and the output signal of the second dividing circuit part 20 has a frequency of 1/2 with respect to the reference clock signal.

Accordingly, in the signal as the result of performing the exclusive-or operation on these two signals by the XOR circuit 31, a high signal is output in areas where the values of the two signals are different, and a low signal is output in areas where the values of the two signals are the same. In addition, as for the signal output from the XOR circuit 31 by synchronizing the signal output from the comparison circuit part 30 with the reference clock signal, the signal output from the XOR circuit 31 is shifted and output as it is.

For this reason, in the abnormality determination part 40, when the comparison circuit part 30 outputs a signal that repeats low and high in a cyclical manner as a signal indicating that the two signals are in different states, by determining that the power supply voltage has become abnormal, it is possible to detect the abnormality of the power supply voltage where the voltage rises to abnormality.

In this way, according to the power supply abnormality detection circuit 1 of the embodiment, power supply abnormalities can be detected using a logic circuit without installing an analog circuit constituted by a reference voltage circuit, a register, a comparator, and the like. For this reason, it is possible to suppress the circuit area, and furthermore, it is possible to suppress the influence of noise.

### Second Embodiment

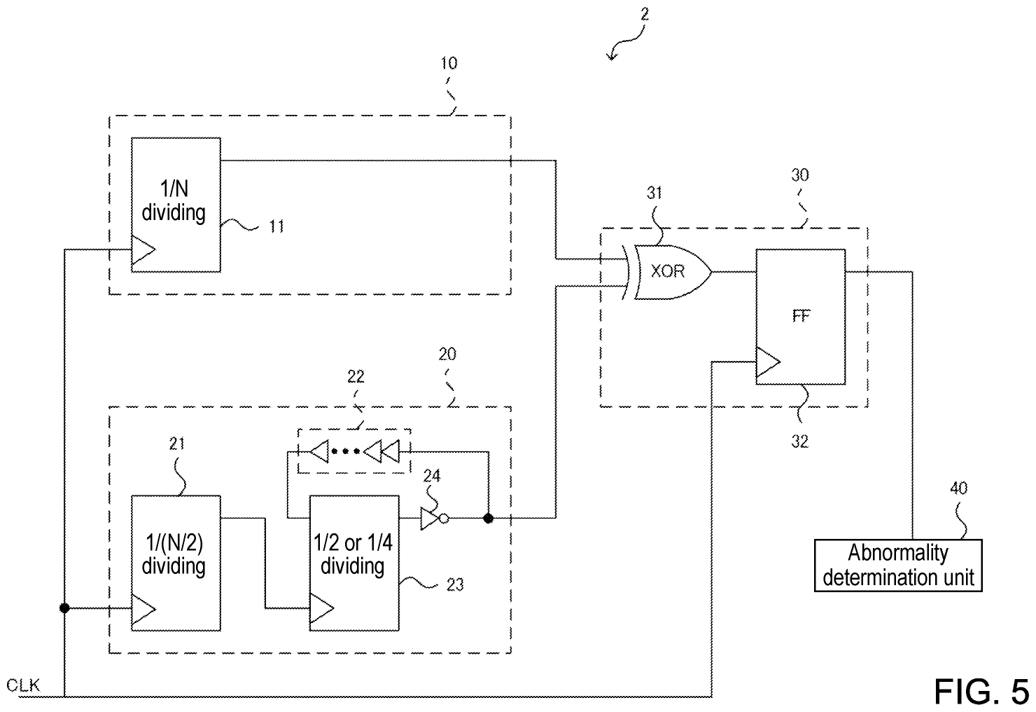

Next, a power supply abnormality detection circuit 2 of a second embodiment of the disclosure will be described. FIG. 5 is a view showing a circuit configuration of the power supply abnormality detection circuit 2 of the second embodiment of the disclosure.

The power supply abnormality detection circuit 1 of the first embodiment is a circuit configured to detect power supply abnormalities when the voltage increases above the normal voltage. On the other hand, the power supply abnormality detection circuit 2 of the embodiment is a circuit configured to detect power supply abnormalities when the voltage decreases below the normal voltage.

The power supply abnormality detection circuit 2 of the embodiment has the same configuration as that of the second dividing circuit part 20 in comparison with the power supply abnormality detection circuit 1 of the first embodiment, and thus, description of the configurations of other elements than the second dividing circuit part 20 will be omitted.

The second dividing circuit part 20 of the power supply abnormality detection circuit 2 of the embodiment divides the frequency of the input clock signal by the frequency of the first ratio at the normal voltage, and divides the frequency of the input signal by a frequency of a second ratio different from the first ratio and outputs the divided frequency at the abnormal voltage.

As shown in FIG. 5, the second dividing circuit part 20 includes the dividing circuit 21 configured to divide the frequency of the input clock signal by the frequency of the ratio of 1/(N/2) and output the divided frequency, the delay circuit 22 configured to change a delay time according to the operating voltage, the flip-flop circuit 23 configured to input the output signal via the delay circuit 22, and the NOT circuit 24 configured to invert the output signal of the flip-flop circuit 23.

The dividing circuit 21 is a circuit in which flip-flop circuits functioning as 1/2 dividing circuits are connected in multiple states to become 1/(N/2) dividing circuits. The flip-flop circuit that constitutes the dividing circuit 21 can use, for example, an edge trigger type D flip-flop circuit.

In the embodiment, N=2 and the first ratio is 1/2. For this reason, the dividing ratio in the dividing circuit 21 becomes 1/(2/2)=1, and dividing of the frequency of the input clock signal is not performed. For this reason, the dividing circuit 21 is omitted.

Further, when N=4 and the first ratio is 1/4, the dividing ratio in the dividing circuit 21 becomes 1/(4/2)=1/2, and 1/2 dividing circuits are connected as the dividing circuit 21.

The delay circuit 22 generates a delay of less than one cycle of the frequency of the clock signal input to the flip-flop circuit 23 at the normal voltage, and generates a delay of one cycle or more and less than two cycles of the frequency of the clock signal input to the flip-flop circuit 23 at the abnormal voltage when the voltage is lowered from the normal voltage.

The delay circuit 22 may have any configuration as long as it is a circuit whose delay time changes depending on the operating voltage, and for example, is constituted by a relay circuit including an inverter such as a metal oxide semiconductor field effect transistor (MOS-FET) relay circuit or the like.

The flip-flop circuit 23 is an edge trigger type D flip-flop circuit like the first embodiment.

In the flip-flop circuit 23 configured as described above, at the normal voltage, the delay time in the delay circuit 22 is less than one cycle of the frequency of the clock signal input to the flip-flop circuit 23, and no setup error occurs in the flip-flop circuit 23.

As a result, in the flip-flop circuit 23, since the output is inverted every rising edge of the clock signal, the frequency of the clock signal input to the flip-flop circuit 23 becomes 1/2.

In addition, when the voltage is abnormal voltage, which is lower than the normal voltage, the delay time in the delay circuit 22 is longer than one cycle of the frequency of the clock signal input to the flip-flop circuit 23, and a setup error occurs.

As a result, in the flip-flop circuit 23, the frequency of the clock signal input to the flip-flop circuit 23 becomes 1/4 because the output is inverted every rising edge of the clock signal with a ratio of once every two pulses of the clock signal.

Accordingly, the flip-flop circuit 23 is a variable dividing circuit that functions as a 1/2 dividing circuit when the voltage is normal, and functions as a 1/4 dividing circuit when the voltage is abnormal voltage that is lower than the normal voltage.

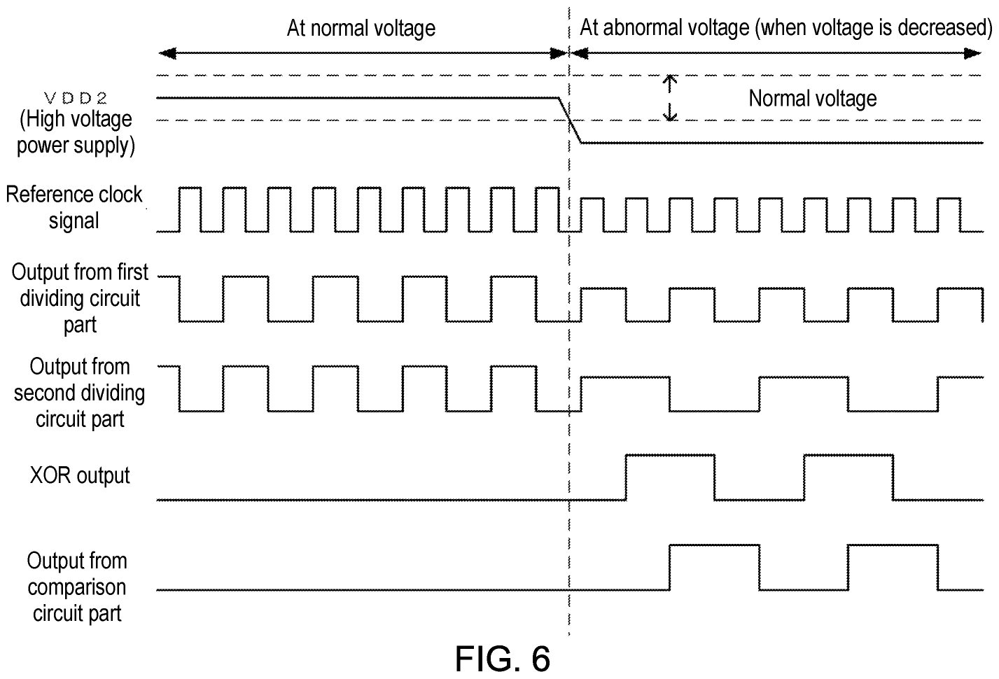

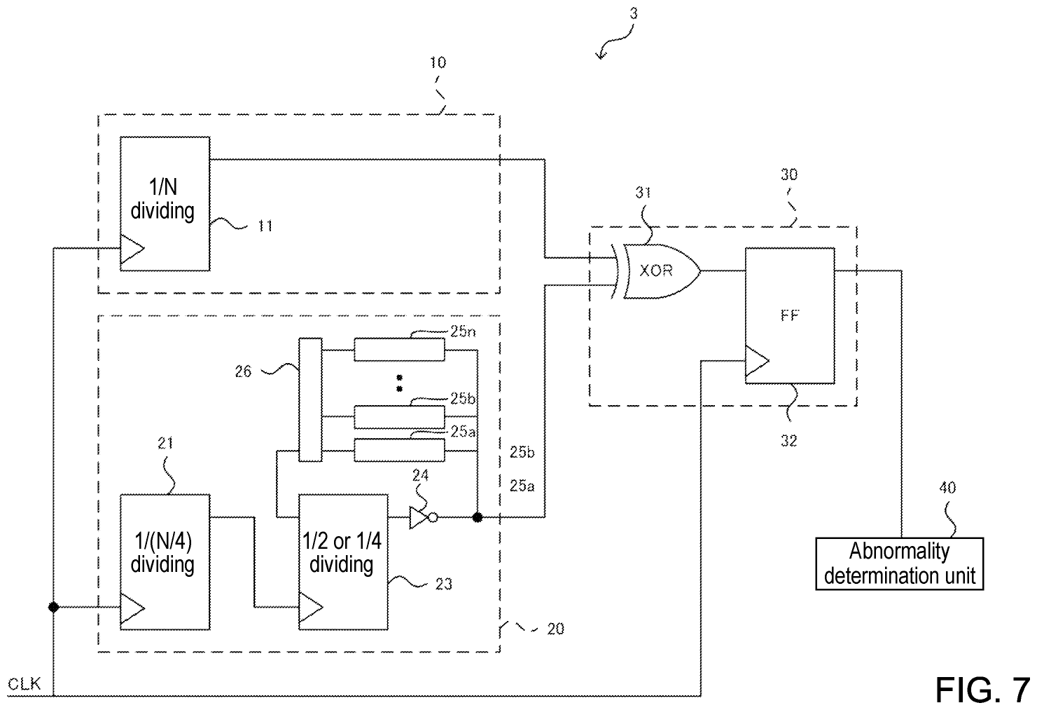

Next, an action of the power supply abnormality detection circuit 2 of the embodiment will be described. FIG. 6 is a timing chart showing a state of a signal in each part of the power supply abnormality detection circuit 2 of the embodiment.

Here, a voltage VDD2 supplied from the high voltage power supply is supplied as the operating voltage of the power supply abnormality detection circuit 2. The voltage VDD2 is, for example, a reference voltage of 3.3 V, and a range of ±0.2 V with the reference voltage of 3.3 V sandwiched therebetween, i.e., a range from 3.1 V to 3.5 V is set as the normal voltage.

The power supply abnormality detection circuit 2 of the embodiment detects the voltage as the abnormal voltage when the voltage decreases below the normal voltage, i.e., when the voltage VDD2 is below 3.1 V.

As shown in FIG. 6, at the normal voltage, the two signals of the output signal of the first dividing circuit part 10 and the output signal of the second dividing circuit part 20 are in the same phase and have a frequency of 1/2 of the reference clock signal.

Accordingly, in the signal as the result of performing the exclusive-or operation by the XOR circuit 31 with respect to these two signals, a low signal is continuously output. In addition, as for the signal output from the comparison circuit part 30 by synchronizing the signal output from the XOR circuit 31 with the reference clock signal, a low signal is continuously output.

On the other hand, when the voltage is the abnormal voltage, which is lower than the normal voltage, the output signal of the first dividing circuit part 10 becomes 1/2 of the frequency of the reference clock signal, and the output signal of the second dividing circuit part 20 becomes 1/4 of the frequency of the reference clock signal.

Accordingly, in the signal as the result of performing the exclusive-or operation by the XOR circuit 31 with respect to these two signals, a high signal is output in a region in which values of the two signals are different, and a low signal is output in a region in which values of the two signals are the same. In addition, even in the signal output from the comparison circuit part 30 by synchronizing the signal output from the XOR circuit 31 with the reference clock signal, the signal output from the XOR circuit 31 is shifted and output as it is.

For this reason, in the abnormality determination part 40, when a signal that repeats low and high in a cyclical manner is outputs from the comparison circuit part 30 as a signal indicating the two signals are in different states, by determining that the power supply voltage has become abnormal, it is possible to detect the abnormality of the power supply voltage where the voltage drops to abnormality.

In this way, the power supply abnormality detection circuit 2 of the embodiment also makes it possible to detect power supply abnormalities using a logic circuit without installing an analog circuit constituted by a reference voltage circuit, a register, a comparator, and the like. For this reason, it is possible to suppress the circuit area, and furthermore, it is possible to suppress the influence of noise.

### Third Embodiment

Next, a power supply abnormality detection circuit 3 of a third embodiment of the disclosure will be described. FIG. 7 is a view showing a circuit configuration of the power supply abnormality detection circuit 3 of the third embodiment of the disclosure.

The power supply abnormality detection circuit 3 of the third embodiment is a circuit configured to detect a case in which the voltage increases above the normal voltage as the power supply abnormality like the power supply abnormality detection circuit 1 of the first embodiment, but is different from the power supply abnormality detection circuit 1 of the first embodiment in that the voltage when the power supply abnormality is detected is variable.

Since the power supply abnormality detection circuit 3 of this embodiment has the same configuration except for the configuration of the second dividing circuit part 20 in comparison with the power supply abnormality detection circuit 1 of the first embodiment, description of the configurations for elements other than the second dividing circuit part 20 will be omitted.

The second dividing circuit part 20 of the power supply abnormality detection circuit 3 of the embodiment divides the frequency of the input clock signal by a frequency of a first ratio at the normal voltage, and divides the frequency of the input signal by a frequency of a second ratio different from the first ratio and outputs the divided frequency at the abnormal voltage.

As shown in FIG. 7, the second dividing circuit part 20 includes a dividing circuit 21 configured to divide the frequency of the input clock signal by a frequency of a ratio of 1/(N/4) and output the divided frequency, a flip-flop circuit 23 configured to input the output signal via the delay circuit 22, a NOT circuit 24 configured to invert the output signal of the flip-flop circuit 23, a plurality of delay circuits 25a, 25b, . . . 25n configured to change a delay time according to an operating voltage, and a selector 26 configured to output one of signals input from the plurality of delay circuits 25a, 25b, . . . 25n.

The plurality of delay circuits 25a, 25b, . . . 25n have different voltages, each at which the delay time changes. For example, the voltage VDD1 supplied from the low voltage power supply is supplied as the operating voltage of the power supply abnormality detection circuit 3. The voltage VDD1 is, for example, a reference voltage of 1.2 V.

In this case, the delay circuit 25a is configured to generate a delay of less than one cycle of the frequency of the clock signal input to the flip-flop circuit 23 in a state in which the voltage VDD1 is less than 1.3 V, and generate a delay of one cycle or more and less than two cycles of the frequency of the clock signal input to the flip-flop circuit 23 in a state in which the voltage VDD1 is 1.3 V or more. That is, in the delay circuit 25a, the delay time changes with a boundary voltage of 1.3 V.

In addition, in the delay circuit 25b, the delay time changes with a boundary voltage of 1.4 V. Similarly, a plurality of delay circuits that each increase the boundary voltage by 0.1 V are provided.

As such a configuration, by switching an input source delay circuit of the signal output from the selector 26 to an arbitrary delay circuit, it is possible to switch the value of the power supply voltage when detecting the abnormality of the power supply voltage where the voltage increases to the abnormality.

For example, when the signal input from the delay circuit 25a is output from the selector 26, if the voltage VDD1 is 1.3V or more, it is detected as the abnormality of the power supply voltage. In addition, when the signal input from the delay circuit 25b is output from the selector 26, if the voltage VDD1 is 1.4V or more, it is detected as the abnormality of the power supply voltage.

Further, as the aspect in which the plurality of delay circuits are installed, it is not limited to the circuit configured to detect the case in which the voltage increases above the normal voltage as the power supply abnormality, and it may be applied to a circuit configured to detect a case in which the voltage is lowered from the normal voltage as the power supply abnormality.

The written contents and the illustrated contents described above are detailed explanations of the parts related to the technology of the present disclosure, and are only an example of the technology of the present disclosure. For example, the above description of the configuration, function, operation, and effect is an example of the configuration, function, operation, and effect of the part related to the technology of the present disclosure. Accordingly, it is needless to say that unnecessary parts can be removed, and new elements can be added or replaced with the contents described and the contents shown above without departing from the spirit of the technology disclosed herein. In addition, in order to avoid confusion and to facilitate understanding of the parts related to the technology of the present disclosure, in the written contents and illustrated contents described above, descriptions regarding common technical knowledge and the like that do not require particular description in order to enable implementation of the technology of the present disclosure are omitted.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A power supply abnormality detection circuit comprising:
a first dividing circuit part configured to divide a frequency of an input clock signal by a frequency of a preset first ratio and output the divided frequency;
a second dividing circuit part configured to divide a frequency of the input clock signal by the frequency of the first ratio when a power supply voltage is a normal voltage, and divide a frequency of an input signal by a frequency of a second ratio different from the first ratio and output the divided frequency when the power supply voltage is an abnormal voltage; and
a comparison circuit part configured to perform comparison of two signals of an output signal of the first dividing circuit part and an output signal of the second dividing circuit part.

2. The power supply abnormality detection circuit according to claim 1, wherein the second dividing circuit part comprises a delay circuit configured to change a delay time according to an operating voltage, and a first flip-flop circuit configured to input the output signal via the delay circuit.

3. The power supply abnormality detection circuit according to claim 2, wherein the delay circuit generates a delay of one cycle or more and less than two cycles of the frequency of the clock signal input to the first flip-flop circuit at the normal voltage, and generates a delay of less than one cycle of the frequency of the clock signal input to the first flip-flop circuit when a voltage is an abnormal voltage that is higher than the normal voltage.

4. The power supply abnormality detection circuit according to claim 2, wherein the delay circuit generates a delay of less than one cycle of the frequency of the clock signal input to the first flip-flop circuit at the normal voltage, and generates a delay of one cycle or more and less than two cycles of the frequency of the clock signal input to the first flip-flop circuit when a voltage is an abnormal voltage that is lower than the normal voltage.

5. The power supply abnormality detection circuit according to claim 1, wherein the comparison circuit part comprises:
a logic circuit configured to perform an exclusive-or operation of an output signal of the first dividing circuit part and an output signal of the second dividing circuit part; and
a second flip-flop circuit configured to synchronize the signal output from the logic circuit with the clock signal input to the first dividing circuit part.

6. The power supply abnormality detection circuit according to claim 2, wherein the comparison circuit part comprises:
a logic circuit configured to perform an exclusive-or operation of an output signal of the first dividing circuit part and an output signal of the second dividing circuit part; and
a second flip-flop circuit configured to synchronize the signal output from the logic circuit with the clock signal input to the first dividing circuit part.

7. The power supply abnormality detection circuit according to claim 3, wherein the comparison circuit part comprises:
a logic circuit configured to perform an exclusive-or operation of an output signal of the first dividing circuit part and an output signal of the second dividing circuit part; and
a second flip-flop circuit configured to synchronize the signal output from the logic circuit with the clock signal input to the first dividing circuit part.

8. The power supply abnormality detection circuit according to claim 4, wherein the comparison circuit part comprises:
a logic circuit configured to perform an exclusive-or operation of an output signal of the first dividing circuit part and an output signal of the second dividing circuit part; and
a second flip-flop circuit configured to synchronize the signal output from the logic circuit with the clock signal input to the first dividing circuit part.

9. The power supply abnormality detection circuit according to claim 5, comprising an abnormality determination part configured to determine that the power supply voltage becomes the abnormal voltage when a signal showing that the two signals are in different states is output from the comparison circuit part.

10. The power supply abnormality detection circuit according to claim 6, comprising an abnormality determination part configured to determine that the power supply voltage becomes the abnormal voltage when a signal showing that the two signals are in different states is output from the comparison circuit part.

11. The power supply abnormality detection circuit according to claim 7, comprising an abnormality determination part configured to determine that the power supply voltage becomes the abnormal voltage when a signal showing that the two signals are in different states is output from the comparison circuit part.

12. The power supply abnormality detection circuit according to claim 8, comprising an abnormality determination part configured to determine that the power supply voltage becomes the abnormal voltage when a signal showing that the two signals are in different states is output from the comparison circuit part.
